(19) United States
(12) Patent Application Publication
(10) Pub. No.: US 2005/0212049 A1
(43) Pub. Date: Sep. 29, 2005

(54) Semiconductor device and process for producing the same

(76) Inventor: Koji Onodera, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/079,786

(22) Filed: Mar. 14, 2005

(30) Foreign Application Priority Data
Mar. 24, 2004 (JP) P2004-087084

(51) Int. Cl. H01L 23/62

(52) U.S. Cl. 257/355

(57) ABSTRACT

A semiconductor device able to improve surge discharge capacity of a protection element (diodes in different direction each other) without changing parameter of a transistor and increasing cost drastically, having a transistor and a protection element at separated regions of semiconductor layers formed on a semiconductor substrate, which the semiconductor layers includes: a barrier layer of nondoped semiconductor formed on its surface with a gate electrode of the transistor; a first conductive type semiconductor region formed in a single or several semiconductor layers including the barrier layer as a topmost layer in a protection element side; and two second conductive type semiconductor regions formed at separated two regions in the barrier layer where the first conductive type semiconductor region is formed, which are formed with protection diodes of different direction each other at contacting surfaces with the first conductive type semiconductor region.

### CROSS REFERENCES TO RERATED APPLICATIONS

The present invention contains subject matter related to Japanese Patent Application JP 2004-087084 filed in the Japanese Patent Office on Mar. 24, 2004, the entire contents of which being incorporated herein by reference.

### BACKGROUND OF THE INVENTION

1. Field of the Invention

The present invention relates to a semiconductor device in which a transistor and a protection element for forming a discharge path of an excess charge in a circuit including the transistor to protect the circuit are formed at separated regions of a plurality of semiconductor layers formed on a semiconductor substrate, and a process for producing the same.

2. Description of the Related Art

As a transistor applying with a plurality of the semiconductor layers as active layers formed on a semiconductor substrate, for example, a Hetero-junction Field Effect Transistor (hereinafter, be referred to a “HFET”) has been known. The HFET has a carrier traveling layer (channel layer), a carrier supplying layer and a barrier layer in a plurality of the semiconductor layers formed on a semi-insulating semiconductor substrate by an epitaxial growth method, and a gate electrode formed on the barrier layer of topmost of that layers controls an electric field of the channel layer to perform a current modulation. The HFET which has been mass production recently uses electron as a carrier, and in usual, is called as a High Electron Mobility Transistor (hereinafter, be referred to as a “HEMT”).

In a semiconductor device, such as the HEMT or an integrated circuit using it (for example a Microwave Monolithic Integrated Circuit: MMIC), a radio frequency property for example noise property or a power gain is satisfactory, but accumulated charges are difficult to flow into the substrate since it is semi-insulated. As a result, break-down strength by an electrostatic discharge (ESD) is low, and if an electrostatic brake-down occurs, production yield of measurements or assembly may be lowered. Therefore, it is need to pay attention sufficiently in handling of the semiconductor device. And the electrostatic brake-down strength is an important factor influencing a reliability of the semiconductor device. In order to secure a safety handling free from a deterioration of the reliability, the withstand voltage with respect to the electrostatic brake-down of the semiconductor device has to be increased sufficiently beforehand.

Corresponding to above requirements, a technology for providing a protection diode at a semi-insulating substrate where a HEMT or other transistors is formed has been known (for example, refer to Japanese Unexamined Patent Publication (Kokai) No. 2002-009253).

The protection diode described in the above document is formed by diffusing a second conductive type impurity, for example zinc (Zn) into separated two regions of a topmost conductive layer that a first conductive type impurity, for example phosphorus (P) is doped. The protection diodes produced by this way are PN-junction diodes formed at respective contacting surfaces with an N-type conductive layer and two P-type Zn diffused layers, and cathodes of the two diodes are connected together to make a back-to-back PNP junction-type diode.

In order to improve a surge discharge capacity to be discharged large amount of charge in short time by the protection diode, it is effective that each PN-junction area of the PNP-type diode is made larger to reduce the respective series resistance. For that purpose, it is effective that a first conductive type conductive layer is formed with large width of its plane pattern, but if the width of the conductive layer becomes large, the pattern area may be large. Consequently, a chip area becomes large and a cost rises.

By making the first conductive type conductive layer thick and making the N-type impurity concentration high, the surge discharge capacity improves. However, the first conductive type conductive layer for the protection diode is formed by simultaneous patterning of an epitaxial growth layer, on which a source electrode or drain electrode of the HEMT or other transistors will be formed, to form the first conductive type cap layer on the same substrate. Therefore, if the epitaxial growth layer makes thick and the N-type concentration makes high, the parasitic capacitance between the respective terminals of a gate and a drain or the date and a source will become increase, as a result a high frequency loss occurs.

If there is provided with the cap layer, the series resistance from the source electrode or drain electrode to the channel layer will become large. So, in a transistor to be considered that reducing of the series resistance is important, the cap layer may be omitted.

In this case, the first conductive type conductive layer has to be formed only for the protection diode by the epitaxial growth and etching, then, cost becomes increasing drastically by that amount.

### SUMMARY OF THE INVENTION

In a semiconductor device forming a protection element at a similar substrate to that of a transistor, it is desirable to improve the surge discharge capacity of the protection element (diodes of different direction each other) without changing parameter and increasing cost of the transistor.

According to an embodiment of the present invention, there is provided a semiconductor device formed with a transistor and a protection element for forming a discharge path of an excess charge of a circuit including the transistor to protect the circuit at separated regions of a plurality of semiconductor layers formed on a semiconductor substrate, the plurality of the semiconductor layers having a barrier layer of nondoped semiconductor formed on its surface with a gate electrode of the transistor; a first conductive type semiconductor region formed in a single or a plurality of semiconductor layers including the barrier layer as a topmost layer in a protection element side; and two second conductive type semiconductor regions formed at separated two regions in the barrier layer where the first conductive type semiconductor region is formed, which are formed with protection diodes of difference direction each other at a respective contacting surfaces with said first conductive type semiconductor region.

According to an embodiment of the present invention, the protection element for protection diodes of different direction each other is formed at least at a part of the barrier layer on which surface a gate electrode of the transistor is formed. The barrier layer is formed from nondoped semiconductor. In the barrier layer, the first conductive type semiconductor region is formed and two second conductive type semiconductor regions are connected via the first conductive type semiconductor region. At a junction surface of one second conductive type semiconductor region and the first conductive type semiconductor region, a protection diode is formed. And another protection diode of reverse direction to the protection diode is formed by another second conductive type semiconductor region and the first conductive type semiconductor region.

When the potential difference occurs by an excess charge of the circuit in the two second conductive type semiconductor regions, one of two protection diodes is biased in forward direction and the other is biased in reverse direction. If the potential difference due to the excess charge is larger than a brake-down voltage of the protection diode of reverse direction, the corresponding excess charge becomes a current flowing the protection element and discharges.

According to the other embodiment of the present invention, there is provided a process for producing the semiconductor device in which a plurality of semiconductor layers including a barrier layer of nondoped semiconductor is formed on a semiconductor substrate to form a transistor and a protection element forming a discharge path of an excess charge of a circuit including the transistor at separated regions of the plurality of semiconductor layers. The process has the steps of injecting a first conductive type impurity into a single or several semiconductor layers including the barrier layer as a topmost layer in the protection element side to form a first conductive type semiconductor region, and injecting a second conductive type impurity into separated two regions in the barrier layer where the first conductive type semiconductor region is formed to form second conductive type semiconductor regions to thereby form protection diodes in different direction each other at a respective contacting surface with the two second conductive type semiconductor regions and the first conductive type semiconductor region.

According to the other embodiment of the present invention, a first conductive type impurity is injected into a single or a plurality of semiconductor layers which has the barrier layer of nondoped semiconductor as a top most layer to form the first conductive type semiconductor region, and a second conductive type impurity is injected into the barrier layer to form the second conductive type semiconductor regions. The selectively injection of impurity, that is injection into a part of the barrier layer, is performed by a formation of a selective mask layer and an ion implantation or a diffusion. Due to this, two protection diodes of difference direction each other are formed.

According to the semiconductor device of a single embodiment of the present invention, two different conductive type regions for protection diodes, that is the first conductive type semiconductor region and the second conductive type semiconductor regions, are formed in the barrier layer of nondoped semiconductor. The barrier layer is similar to a barrier layer formed beneath a gate electrode of the transistor and relatively thick. Further, the first conductive type semiconductor region may be formed deeply to a semiconductor layer under the barrier layer. Due to this, junction areas of the protection diodes can be made large and a concentration of the first conductive type semiconductor region can be set arbitrarily corresponding to the specification of the protection element. Due to this, the surge remove capacity of the protection element can be improve without changing parameters of the transistor.

According to the process for producing the semiconductor device of a single embodiment of the present invention, the first conductive type semiconductor region and the second conductive type semiconductor region can be formed by selective impurity injecting methods. The selective impurity injecting method is performed in lower cost than a formation of an epitaxial growth layer or other semiconductor layer, therefore the cost increase according to form the protection element can be suppressed.

### BRIEF DESCRIPTION OF THE DRAWINGS

These and other objects and features of the present invention will be described in more detail with reference to the accompanying drawings, in which:

FIG. 1 is a schematic cross-sectional view of a semiconductor device according to an embodiment of the present invention;

FIG. 2A, FIG. 3A, FIG. 4A, FIG. 5A, FIG. 6A and FIG. 7A are cross-sectional views at some mid-flow of procedure of a process for a protection element side of the semiconductor device according to a first embodiment of the present invention;

FIG. 2B, FIG. 3B, FIG. 4B, FIG. 5B, FIG. 6B and FIG. 7B are cross-sectional views at some mid-flow of procedure of a process for a HEMT side of the semiconductor device according to the first embodiment of the present invention;

FIG. 8A, FIG. 9A, FIG. 10A, FIG. 11A, FIG. 12A and FIG. 13A are cross-sectional views at some mid-flow of procedure of a process for a protection element side of the semiconductor device according to a second embodiment of the present invention; and

FIG. 8B, FIG. 9B, FIG. 10B, FIG. 11B, FIG. 12B and FIG. 13B are cross-sectional views of a comparative example at some mid-flow of procedure of a process according to the second embodiment of the present invention.

### DESCRIPTION OF THE PREFERRED EMBODIMENTS

Next, preferred embodiments of the present invention will be explained with reference to the drawings and with examples in the case of using a HEMT as a transistor.

### First Embodiment

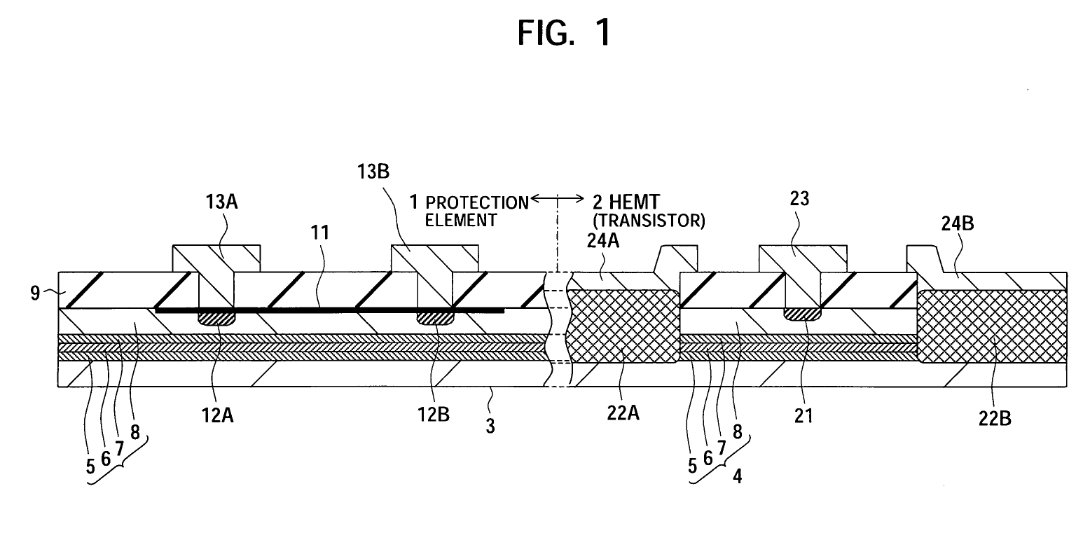

FIG. 1 is a schematic cross-sectional view of a semiconductor device according to the present embodiment.

In FIG. 1, a protection element 1 and a HEMT 2 are formed on a same substrate. In a case of using circuits including the HEMT 2, for example, a case that the semiconductor device according to the present embodiment is a front-end MMIC for radio communication using the HEMT 2 as a low noise amplification element, the protection element 1 is integrated together with the HEMT 2 and passive elements such as a capacitor, a resistance and an inductor on the same substrate. The elements except the HEMT are omitted to show in the drawing. The protection element 1 is, for example, connected between a node to be prevented from charging and a reference potential node in a circuit via not shown interconnections, and discharged the node to be prevented from charging with an excess charge, which flow as a current (hereinafter, be referred to a “surge current”) to a reference potential, for example a ground potential. The respective active regions of a circuit unit including the HEMT and a protection element unit are electrically insulated and isolated by an element isolating insulation layer not shown in the drawing, for example.

The protection element 1 and the HEMT 2 have a common substrate configuration which has a plurality of semiconductor layers 4, for example four epitaxial growth layers formed on a GaAs or other semi-insulating semiconductor substrate 3. As the plurality of semiconductor layers 4, there are an electron traveling layer 5, a spacer layer 6, an electron supplying layer 7 and a barrier layer 8 formed successively from bottom layer by epitaxial growth methods. Note that, if necessary, as interlayer thereof may be formed a thin buffer layer not shown.

The four semiconductor layers 5 to 8 include, for example, the electron traveling layer 5 of nondoped GaAs, the spacer layer 6 of nondoped AlₓGa₁₋ₓAs (x=0.2 to 0.3), the electron supplying layer 7 of an n-type AlₓGa₁₋ₓAs doped Si, and the barrier layer 8 of nondoped AlₓGa₁₋ₓAs.

The electron supplying layer 7 and the electron traveling layer 5 have a difference of an electron affinity of its materials, and the electron supplying layer 7 is formed by injection of an n-type impurity (donor), so it has a work-function differing from that of the electron traveling layer 5. As a result, a bent of band occurs at an energy discontinuity region of a hetero junction surface in thermal equilibrium. This is because that an electron is generated from a donor in the electron supplying layer 7 side and moves in the electron traveling layer 5, so that the donor is depleted in the edge portion of the electron supplying layer 7. The electron in the electron traveling layer 5 is distributed in extremely shallow range with 2-dimention, therefore referred to a “2-dimentional electron gas”, and spatially separated from the donor which generated it. Therefore, the electron is free from influence of the impurity chattering, so a transistor channel in which it can move at extremely high speed is formed.

In the HEMT 2, a zinc (Zn) is injected by diffusion, and then a junction gate region 21 is formed in a surface portion of the topmost barrier layer 8.

On the other hand, in a surface portion of the barrier layer 8 of the protection element 1 side, a first conductive type semiconductor region 11 which has the first conductive type (in the present embodiment, an N-type) is formed. A channel of surge current is formed in the first conductive type semiconductor region 11. At two separated regions in the barrier layer 8 where the first conductive type semiconductor region 11 is formed, two second conductive type semiconductor regions 12A and 12B, which are the second conductive type (in the present embodiment, a P-type) and have a similar depth and a similar impurity concentration, are formed at the same time of formation of the junction gate region 21 of the HEMT 2 side. Due to this, a PN-junction diodes is formed at the contacting surface with the second conductive type semiconductor region 12A and the first conductive type semiconductor region 11. And another PN-junction diode of different direction is formed at the contacting surface with the second conductive type semiconductor region 12B and the first conductive type semiconductor region 11.

On the barrier layer 8, an insulation film 9 made of silicon nitride etc., which is opened at upper surface portions of the second conductive type semiconductor regions 12A, 12B and the junction gate region 21, is formed. Electrode material, for example Ti/Au or other inactive metal material is buried in the apertures of the insulation film 9. Due to this, electrodes 13A and 13B connecting respectively to one of upper surfaces of the second conductive type semiconductor regions 12A and 12B are formed in the protection element 1 side, and a gate electrode 23 connecting to an upper surface of the junction gate region 21 is formed in the HEMT 2 side.

Note, in the HEMT 2 side, ohmic metals, for example ohmic connecting layers 22A and 22B which are formed by alloying GaAs with AgGe/Ni is formed so as to reach the channel layer at locations separated both sides of the gate electrode 23, and source and drain electrodes 24A and 24B made of inactive metal materials such as Ti/Pt/Au are formed on those ohmic metals. Note that, an ohmic electrode configuration is not formed on the protection element 1 side.

In order to form an MMIC or other circuit, an upper layer wiring is formed above the HEMT 2 via an interlayer insulation layer according to need, but it is omitted in the drawing.

In the protection element 1 having above configuration, two PN-junction diodes of different directions each other are formed by the first conductive type semiconductor region 11 and the two second conductive type semiconductor regions 12A and 12B. The electrodes 13A and 13B are connected to a not shown circuit (including the HEMT), so that a surge applied to the circuit or the charge due to electrostatic causes a potential difference to the two second conductive type semiconductor regions 12A and 12B. Then, due to the potential difference, one PN-junction diode is biased in forward direction and another PN-junction diode is biased in reverse direction. If a supplied potential difference is larger than a break-down voltage of the diode in reverse direction, the excess current (excess charge) may flow between the two diodes. As a result, the surge applied to the circuit or the charge due to electrostatic is discharged immediately and the circuit can be protected.

In order to improve the ability that the protection element 1 can discharge electrons rapidly, it is important that a resistance of the discharge path is small and a current capacity thereof is large. They are determined by a size of junction areas of the PN-junction diodes and a distribution profile of the N-type impurities which mainly decides a resistance of the first conductive type semiconductor region 11.

In the present embodiment, since the first conductive type semiconductor region 11 is not shared in the HEMT 2 side, there is an advantage that a concentration, a depth and a distribution profile of impurities can be set in order to meet a requirement of the protection element 1 side. Therefore, the flexibility of design of it is high and it can be formed easily.

Note that, in FIG. 1, although the first conductive type semiconductor region 11 is formed thin in a surface portion of the barrier layer 8, it can be formed deeper than the second conductive type semiconductor regions 12A and 12B. In this case, there is an advantage that a size of junction area can be large. Also, the first conductive type semiconductor region 11 can be formed to the specific layer in the plurality of the semiconductor layers 4 having the barrier layer 8 as a topmost layer. In other words, the donor of the HEMT channel is the N-type, and this respect is common to the first conductive type semiconductor region 11, so that the electron supplying layer 7 supplying electrons to the HEMT channel and the electron traveling layer 5 can be utilized as a part of the channel of the protection diodes. In this case, when the surge current is relativity low, it is considered that the semiconductor layers 5 to 7 for forming a deep HEMT channel are rarely utilized as the channel of the protection diodes. However, if the excess surge current flows, the current will flow to the semiconductor layers 5 to 7. As a result, in the present embodiment, the surge current capacity of the protection element 1 can be made large extremely.

Next, the process for producing the semiconductor device shown in FIG. 1 will be described.

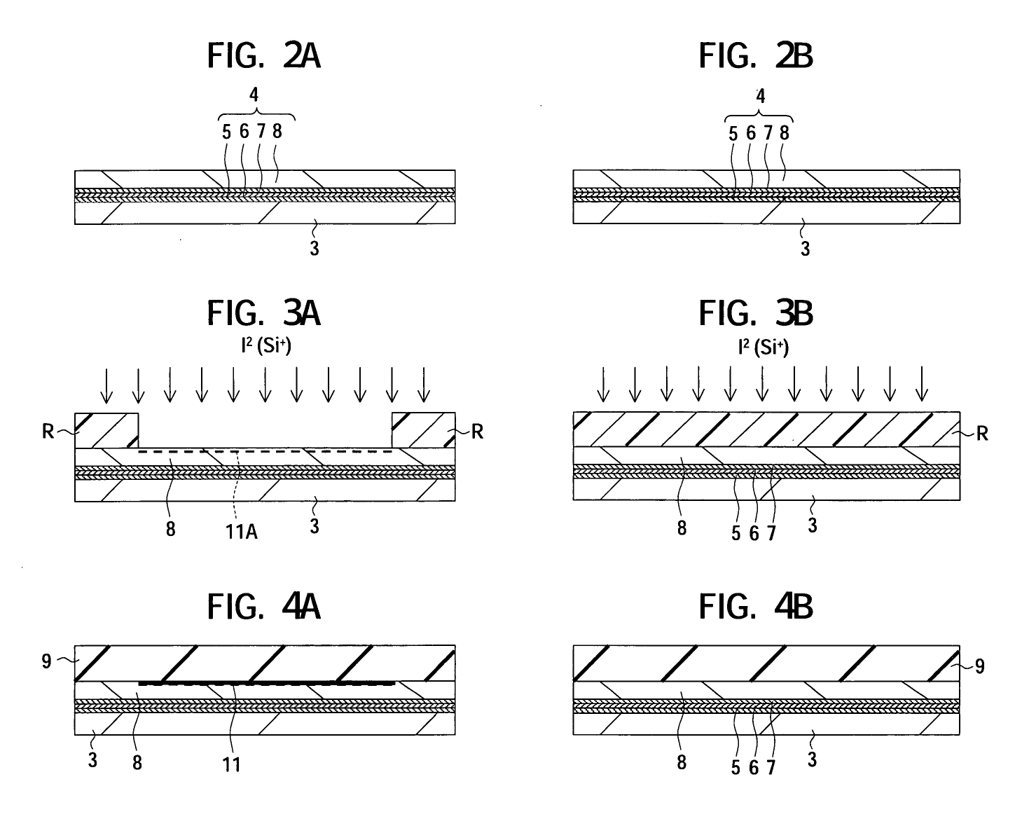

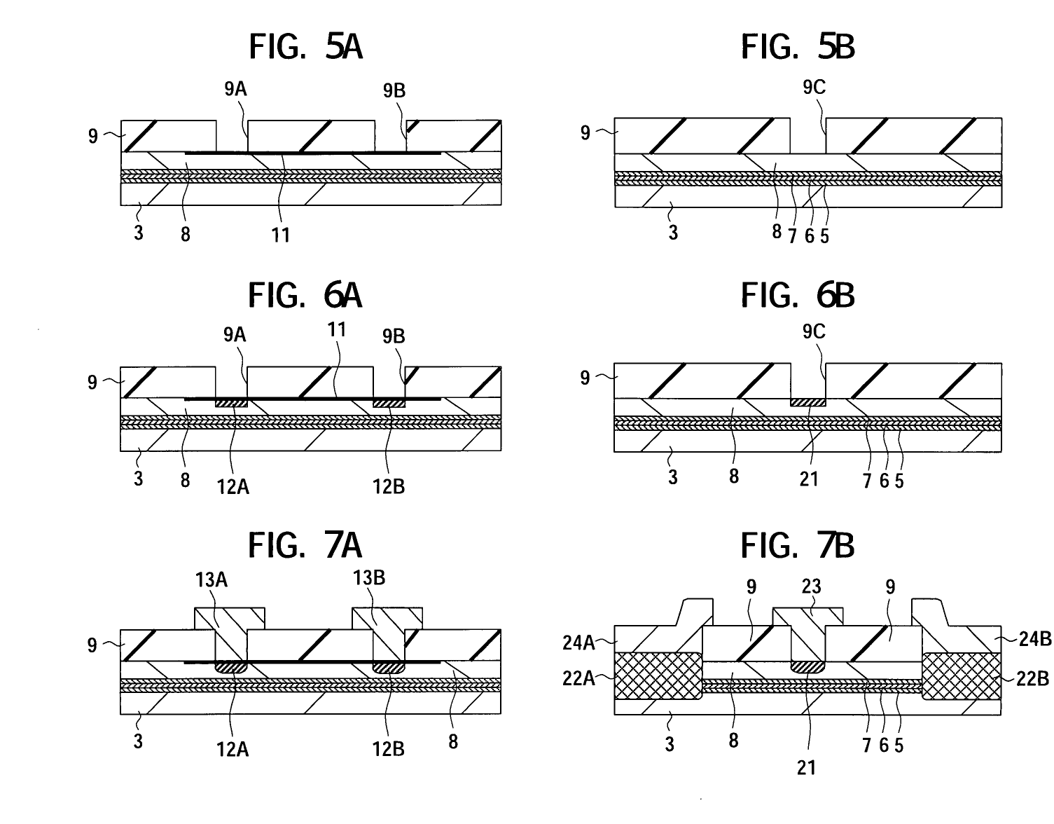

FIGS. 2A to 7B show cross-sectional views at some mid-flow of procedure of the processes for the semiconductor device. FIG. 2A, FIG. 3A, FIG. 4A, FIG. 5A, FIG. 6A and FIG. 7A show cross-sectional views of the protection element 1 side, and FIG. 2B, FIG. 3B, FIG. 4B, FIG. 5B, FIG. 6B and FIG. 7B show cross-sectional views of the HEMT 2 side.

The electron traveling layer 5, the spacer layer 6, the electron supplying layer 7 and the barrier layer 8 are formed by epitaxial growth methods such as MOCVD or MBE on a prepared semiconductor substrate 3 as shown in FIGS. 2A and 2B. The methods will be explained as following.

On the semiconductor substrate 3, a nondoped GaAs is growth several 100 nm to form the electron traveling layer 5. Then, on the electron traveling layer 5, a nondoped AlGaAs layer is growth several to over 10 nm to form the spacer layer 6, further an N-type of AlGaAs is growth several to over 10 while doping Si to form the electron supplying layer 7. Due to this, a 2-dimentional electron gas (2DEG) layer is formed in a facing part of the electron traveling layer 5 which is opposite to the electron supplying layer 7. Further, on the electron supplying layer 7, a nondoped AlGaAs is growth over 10 to 100 tens nm, for example 100 to 130 nm, to form the barrier layer 8.

In the process shown in FIG. 3A, an injection of impurities for the first conductive type semiconductor region 11 is performed by an ion implantation.

By using a photolithography technology, a coated photoresist is patterned to form an aperture opening only the protection element 1 side, and by using the patterned photoresist R as a mask, first conductive type impurities, for example ions of silicon (Si) as N-type dopant are injected. A condition for injecting ion in this case is important for deciding the surge remove capacity of the protection element 1, as an example, a dosage of Si ion is 5×10¹³ cm² and energy is 150 keV. Note that, as a method forming the first conductive type semiconductor region 11 deeply as mentioned above, it is possible to adopt a method increasing the injection energy, a method changing injection energy and performing ion implantation at several times, further, a thermal diffusion method or a method performing both a thermal diffusion and an ion implantation.

Then, as shown in FIG. 3A, an N-type impurity injected layer 11A is formed at a part of the barrier layer 8 of the protection element 1 side. In contrast, as shown in FIG. 3B, the HEMT 2 side is covered with a resist R and is not performed with the injection of impurities.

After removing the photoresist R, as shown in FIGS. 4A and 4B, a silicon nitride film as an insulation layer 9 is deposited, for example with 300 nm of thickness, then a rapid thermal annealing (RTA) is performed at 900° C. for 30 sec. to activate the n-type impurity layer 11A performed ion implantation. In this way, the first conductive type semiconductor layer 11 in high conductivity is formed in the barrier layer 8. Note, in the case of forming the first conductive type semiconductor layer 11 to deeper position in the barrier layer 8 or to lower layer, the specific activation method suitable to the impurity injection method can be adopted.

In the step of FIGS. 5A and 5B, in the protection element 1 side, a not shown photoresist is patterned to form two apertures which are separated in the first conductive type semiconductor region 11, and parts of the insulation film 9 exposed by the apertures are etched off to form apertures 9A and 9B. At the same time, in the HEMT 2 side, the photoresist is patterned to form an aperture exposed a part of the barrier layer 8, and a part of the insulation film 9 exposed by the aperture is etched off to form an aperture 9C. In this way, the aperture 9C for the gate electrode of the HEMT 2 side and the apertures 9A and 9B of the protection element 1 side are formed simultaneously.

After that, the photoresist is removed.

Then, as shown in FIGS. 6A and 6B, using the insulation film 9 as a selective mask, impurities to be the second conductive type dopant, for example zinc (Zn), are diffused. At that time, in the protection element 1 side, zincs are diffused passing though the two apertures 9A and 9B to the barrier layer 8 to form the two second conductive type semiconductor regions 12A and 12B, and in the HEMT 2 side, zincs are diffused passing though the gate aperture 9C to the barrier layer 8 to form the junction gate region 21.

In the present invention, a method for injecting the second conductive type impurity is not limited to the diffusion method. However, since the junction gate region 21 of the HEMT 2 has to be made high concentration and thin layer, a vapor phase zinc diffusion method is desirable to adopt. As an example of the diffusing condition, for example, it may be performed in gas atmosphere containing diethyl zinc (Zn(C₂H₅)₂) and arsenic trihydride AsH₃ at almost 600° C.

In the step as shown in FIGS. 7A and 7B, a metal film to be an ohmic connection layer is formed selectively only in the HEMT 2 side. In the film formation, for example by using an electron beam evaporation method, AuGe/Ni are deposited almost 160 nm and 40 nm. Then, by selective removal, an unnecessary portion of the metal film is removed and thermal treatment of several 100° C. performed in a forming gas, then ohmic connection layers 22A and 22B reaching the channel (2DEG layer) are formed as shown in FIG. 7B. Note, if the ohmic connection layers 22A and 22B are not reached to the channel since a plurality of semiconductor layers 4 makes thick, a satisfactory operation may be possible.

Next, a not shown photoresist is patterned and then a metal film to be electrodes is formed entirely on the resist upper surface. In the film formation, for example, by using the electron beam evaporation method, Ti/Pt/Au are deposited about 30/50/120 nm each other. After that, the photoresist and the unnecessary part of the metal film are together removed (lifted off) to form two electrodes 13A and 13B in the protection element 1 side, and in parallel with this, a gate electrode 23 and source and drain electrodes 24A and 24B are formed in the HEMT 2 side.

Note that, not limited to this lift-off method, for example, it may be performed that a photoresist pattern is formed on the metal film and an excess portion is removed by an ion milling.

After that, a source electrode and a drain electrode not shown are formed and if necessary, an upper layer interconnection is formed via an interlayer insulation film, whereby the HEMT is completed.

In this process, a HEMT process is applied as well as possible and processes added for forming the protection element 1 are only the patterning of the photoresist R shown in FIG. 3A and the ion implantation or other impurity injection process, as a result, increasing of cost is low. And parameters of the transistor are not changed for this process.

### Second Embodiment

The present embodiment is related to a case that the plurality of semiconductor layers 4 formed on the semiconductor substrate 3 of the HEMT includes a cap layer 10 which is upper layer than the barrier layer 8.

Note, since the present embodiment differs from the first embodiment at the point of only forming the cap layer 10, the deference will mainly be explained, for components the same as those of the first embodiment the same reference numerals are assigned and their explanation will be omitted.

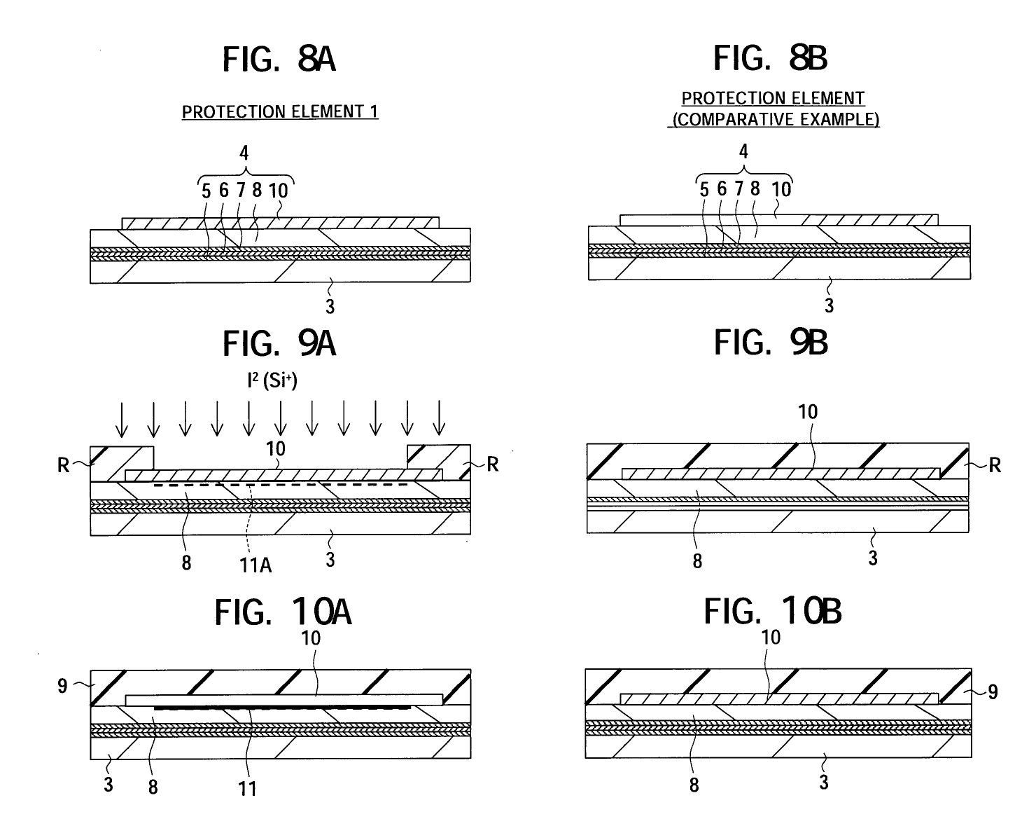

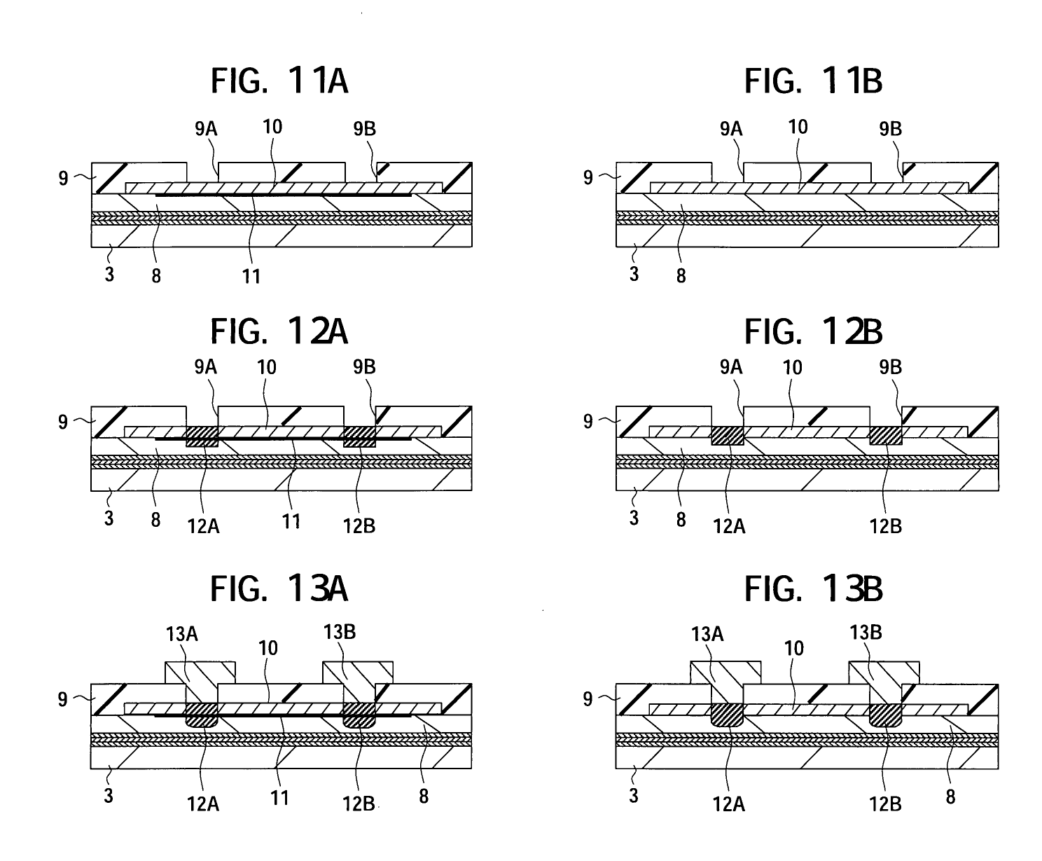

FIG. 8A, FIG. 9A, FIG. 10A, FIG. 11A, FIG. 12A and FIG. 13A show the protection element 1 at some mid-flow of procedure of the present embodiment, and as a comparative example, FIG. 8B, FIG. 9B, FIG. 10B, FIG. 11B, FIG. 12B and FIG. 13B show the case of applying the cap layer 10 as a channel of the protection element and not forming the first conductive type semiconductor region 11.

The cap layer 10 is layer selectivity remained after epitaxial growth at regions where the ohmic connection layers 22A and 22B to be source and drain of the HEMT 2 are formed. Further, it has an effect to reduce a source resistance influencing especially on high frequency characteristics.

In FIGS. 8A and 8B, in the formation of the cap layer 10, after forming the barrier layer 8, for example an N-type GaAs doped Si is formed several 10 nm by epitaxial growth method. The concentration of the N-type impurity is set to 10¹⁸ order as relatively high.

Further, a photoresist is coated and patterned, and then a part of the cap layer 10 whereon the photoresist is not formed is selectively removed by etching. As a result, the cap layer 10 for the protection element is formed such as the drawing. After that, the photoresist is removed.

In the step of FIG. 9A, an ion implantation is performed passing though the cap layer 10 to make the conductive type of a surface portion of the underling barrier layer 8 negative. Although to make conductive type negative is performed in any degree, in the present embodiment, the condition for ion implantation is set so as to supplement with a surge current capacity of the cap layer 10. Therefore, if the surge current capacity of the cap layer 10 is insufficiency further, as similar to the first embodiment, the ion implantation can be performed to the semiconductor layers being lower than the barrier layer 8. Note, in the comparative example as shown in FIG. 9B, the cap layer is protected by a resist R and the ion implantation is not performed.

After that, by similar methods to the first embodiment, the insulation film 9 is formed (FIGS. 10A and 10B), the apertures 9A and 9B are formed (FIGS. 11A and 11B), zinc diffusion is performed (FIGS. 12A and 12B), and the electrodes are formed (FIGS. 13A and 14B), whereby the protection element 1 and the HEMT 2 (not shown) are completed.

According to the present embodiment in comparison with the comparative example, due to only adding a simple process shown in FIG. 9A, it is possible that the size of the injection area of the protection element is enlarged and the surge removing capacity is improved.

It should be understood by those skilled in the art that various modifications, combinations, sub-combinations and alterations may occur depending on design requirements and other factors in so far as they are within scope of the appeared claims or the equivalents thereof.

1. A semiconductor device formed with a transistor and a protection element for forming a discharge path of an excess charge of a circuit including said transistor to protect said circuit at separated regions of a plurality of semiconductor layers formed on a semiconductor substrate, said plurality of the semiconductor layers comprising:
a barrier layer of nondoped semiconductor formed on its surface with a gate electrode of said transistor;
a first conductive type semiconductor region formed in a single or a plurality of semiconductor layers including said barrier layer as a topmost layer in a protection element side; and
two second conductive type semiconductor regions formed at separated two regions in said barrier layer where said first conductive type semiconductor region is formed, which are formed protection diodes of difference direction each other at a respective contacting surfaces with said first conductive type semiconductor region.

2. A semiconductor device as set forth in claim 1, further comprising:
a conductive layer of first conductive type semiconductor stacked on said barrier layer in said protection side, wherein
said two second conductive type semiconductor regions are formed penetrating said conductive layer in thickness direction.

3. A semiconductor device as set forth in claim 1, wherein said two second conductive type semiconductor regions have a similar depth and a similar impurity concentration to a second conductive type junction gate region beneath a gate electrode of said transistor.

4. A semiconductor device as set forth in claim 2, wherein:
said two second conductive type semiconductor regions have a similar depth and a similar impurity concentration to a second conductive type junction gate region beneath a gate electrode of said transistor, and
said conductive layer has a similar thickness and a similar impurity concentration to two cap layers where a source electrode and a drain electrode of said transistor are formed.

5. A process for producing a semiconductor device in which a plurality of semiconductor layers including a barrier layer of nondoped semiconductor is stacked on a semiconductor substrate to form a transistor and a protection element forming a discharge path of an excess charge of a circuit including said transistor at separated regions of said plurality of semiconductor layers, comprising the steps of:
injecting a first conductive type impurity into a single or several semiconductor layers including said barrier layer as a topmost layer in said protection element side to form a first conductive type semiconductor region, and
injecting a second conductive type impurity into separated two regions of said barrier layer where said first conductive type semiconductor region is formed to form second conductive type semiconductor regions to thereby form protection diodes of different direction each other at a respective contacting surface with said first conductive type semiconductor region.

6. A process for producing a semiconductor device as
set forth in claim 5, further comprising a step of
forming a conductive layer of a first conductive type semiconductor on said barrier layer in said protection element side, and wherein,
in the step of forming said protection diode, said two second conductive type semiconductor regions are formed penetrating said conductive layer in thickness direction.

7. A process for producing a semiconductor device as set forth in claim 5, wherein said two second conductive type semiconductor regions of said protection element side are formed simultaneously with a second conductive type junction gate region on which surface the gate electrode of said transistor is formed.

8. A process for producing a semiconductor device as set forth in claim 6, wherein
a conductive layer of said protection element side is formed from a semiconductor layer as similar to two cap layers on which surface a source electrode and a drain electrode of said transistor are formed, and
said two second conductive type semiconductor regions of said protection element side are formed simultaneously with a second conductive type junction gate region on which surface the gate electrode of said transistor is formed.
